(19) United States
(12) Patent Application Publication
(10) Pub. No.: US 2020/0062783 A1
(43) Pub. Date: Feb. 27, 2020

(54) PHOTO LEWIS ACID GENERATOR

(71) Applicant: Nippon Shokubai Co., Ltd., Osaka (JP)

(72) Inventors: Tomoaki Tanaka, Osaka (JP); Satoshi Ishida, Osaka (JP); Toshifumi Nishida, Osaka (JP)

(21) Appl. No.: 16/466,255

(22) PCT Filed: Dec. 1, 2017
(86) PCT No.: PCT/JP2017/043372

§ 371 Date: Jun. 3, 2019

(30) Foreign Application Priority Data
Dec. 8, 2016 (JP) 2016-238916

(51) Int. Cl. C07F 5/02; G03F 7/029; C08F 2/50

(52) U.S. Cl. CPC C07F 5/02; C08F 2/50; G03F 7/0295

(57) ABSTRACT

Provided is a compound capable of generating a Lewis acid in response to light unlike conventional photo acid generators. The compound comprises an anionic moiety having a central boron atom and a particular cationic moiety (for example, a cation having a HOMO-LUMO gap of 5.3 eV or less). The cationic moiety may, for example, have a skeleton selected from an N-substituted pyridinium skeleton, an N-substituted bipyridinium skeleton, an N-substituted quinolinium skeleton, and a pyrylium skeleton.

### TECHNICAL FIELD

The present invention relates to a compound capable of generating a Lewis acid in response to light (light energy) irradiation and to a composition comprising the compound.

### BACKGROUND ART

Acid generators are compounds that generate a protonic acid (Bronsted acid) in response to light or heat, and have been used as a polymerization initiator, a chemically amplified resist, and the like (see Patent Literature 1 to 3).

### CITATION LIST

### Patent Literature

Patent Literature 1: JP 2014-205624 A

Patent Literature 2: JP 2014-214129 A

Patent Literature 3: JP 2001-183821 A

### SUMMARY OF INVENTION

### Technical Problem

The present invention is intended to provide a compound capable of generating a Lewis acid in response to light, a photo Lewis acid generator comprising the compound, and a composition comprising the compound or the generator.

### Solution to Problem

Conventional photo acid generators comprise, as a cationic moiety, a component that generates a protonic acid in response to light or heat and, as an anionic moiety, an inorganic anion such as SbF₆⁻ and BF₄⁻ or an organic anion such as (C₆F₅)₄B⁻. These generators, however, have drawbacks in that they are usable only in systems that can utilize a protonic acid and are required to contain a toxic metal such as antimony in the anionic moiety. Therefore, there is still much to be improved.

In such circumstances, the inventors of the present invention have carried out intensive studies to create a compound capable of generating a Lewis acid in response to light, which is conceptually quite different from conventional photo acid generators. As a result, the inventors of the present invention have found that a combination of an anionic moiety having a central boron atom with a particular cationic moiety enables production of a compound (photo Lewis acid generator) capable of generating a Lewis acid from the anionic moiety. The acid generated from such a compound is a Lewis acid, which has different reactivity from that of the protonic acid, and is generally a strong Lewis acid having a central boron atom. Therefore, the acid from such a compound is highly useful.

The inventors of the present invention have further obtained new findings as described below, and as a result of further intensive studies, have completed the present invention.

That is, the compound of the present invention is a compound that comprises an anionic moiety having a central boron atom and a cationic moiety (a salt of a cationic moiety and an anionic moiety) and is capable of generating a Lewis acid (specifically, a Lewis acid having a central boron atom) from the anionic moiety in response to light irradiation.

More particularly, the compound of the present invention may be a compound that comprises an anionic moiety having a central boron atom and an aryl group containing at least one halogen atom and a cationic moiety and is capable of generating a Lewis acid from the anionic moiety in response to light irradiation.

### Advantageous Effects of Invention

The compound (photo Lewis acid generator) of the present invention can generate a Lewis acid in response to light. Therefore, the compound can be applied to various applications that can utilize a Lewis acid (for example, photoinitiators (photo-latent initiators) and chemically amplified resists).

Moreover, the compound of the present invention comprises boron as the central atom of the anionic moiety, does not need to contain such a metal as antimony, and is therefore highly safe and very useful.

### DESCRIPTION OF EMBODIMENTS

### Compound

The compound of the present invention comprises an anionic moiety having a central boron atom and a cationic moiety. The anionic moiety can generate a Lewis acid (a Lewis acid having a central boron atom) in response to light irradiation.

### Anionic Moiety

The anionic moiety may be any anionic moiety that has a central boron atom and can generate a Lewis acid in response to light. The groups (or atoms) attached (bonded) to the boron atom (>B<) that is the central atom of the anionic moiety (or the boron anion (>B<)⁻) are not particularly limited, and examples include hydrocarbon groups, heterocyclic groups (a heteroaryl group and the like), a hydroxy group, halogen atoms, and a hydrogen atom.

Examples of the hydrocarbon group include aliphatic hydrocarbon groups [for example, alkyl groups (including C₁₋₂₀ alkyl groups such as a methyl group, an ethyl group, an n-propyl group, an isopropyl group, an n-butyl group, an s-butyl group, a t-butyl group, an n-pentyl group, an n-hexyl group, an n-heptyl group, an n-octyl group, and a 2-ethylhexyl group, preferably C₂₋₁₀ alkyl groups, more preferably C₂₋₆ alkyl groups), cycloalkyl groups (including C₃₋₂₀ cycloalkyl groups such as a cyclopentyl group and a cyclohexyl group, preferably C₄₋₈ cycloalkyl groups), and aralkyl groups (including C₆₋₁₀ aryl-C₁₋₄ alkyl groups such as a benzyl group and a phenethyl group)], and aromatic hydrocarbon groups [for example, aryl groups (including C₆₋₂₀ aryl groups such as a phenyl group, a tolyl group, a xylyl group, and a naphthyl group, preferably C₆₋₁₂ aryl groups, more preferably C₆₋₁₀ aryl groups)].

The hydrocarbon group and the heterocyclic group may have a substituent. The hydrocarbon group having a substituent means that one or more hydrogen atoms of an unsubstituted hydrocarbon group are substituted by substituents, and the heterocyclic group having a substituent means that one or more hydrogen atoms of an unsubstituted heterocycle are substituted by substituents. The substituent may be further substituted with a substituent.

The substituent is not particularly limited, and examples include halogen atoms (for example, a fluorine atom, a chlorine atom, a bromine atom, and an iodine atom), a hydroxyl group, alkoxy groups (for example, C₁₋₂₀ alkoxy groups such as a methoxy group and an ethoxy group, preferably C₁₋₁₀ alkoxy groups, more preferably C₁₋₄ alkoxy groups), aryloxy groups (for example, C₆₋₁₀ aryloxy groups such as a phenoxy group), acyl groups (for example, C₁₋₁₀ alkylcarbonyl groups such as an acetyl group; and C₆₋₁₀ arylcarbonyl groups such as a benzoyl group), acyloxy groups (for example, C₁₋₁₀ alkylcarbonyloxy groups such as an acetoxy group; and C₆₋₁₀ arylcarbonyloxy groups such as a phenylcarbonyloxy group), alkoxycarbonyl groups (for example, C₁₋₁₀ alkoxycarbonyl groups such as a methoxycarbonyl group), aryloxycarbonyl groups (for example, C₆₋₁₀ aryloxycarbonyl groups such as a phenoxycarbonyl group), a mercapto group, alkylthio groups (for example, C₁₋₂₀ alkylthio groups such as a methylthio group, preferably C₁₋₁₀ alkylthio groups, more preferably C₁₋₄ alkylthio groups), arylthio groups (for example, C₆₋₁₀ arylthio groups such as a phenylthio group), an amino group, substituted amino groups (for example, mono- or di-C₁₋₄ alkylamino groups such as a dimethylamino group), amido groups (for example, mono- or di-C₁₋₄ alkylaminocarbonyl groups such as an N,N′-dimethylaminocarbonyl group), a cyano group, a nitro group, substituted sulfonyl groups (for example, C₁₋₁₀ alkylsulfonyl groups such as a mesyl group, and C₆₋₁₀ arylsulfonyl groups such as tosyl groups), and hydrocarbon groups (for example, the aforementioned exemplary hydrocarbon groups including alkyl groups).

These substituents may be used alone, and also two or more of them may be used in combination. The hydrocarbon group or the heterocyclic group may have one or more substituents.

One or more of these substituents may be directly bonded to the boron atom.

In preferred embodiments, the anionic moiety may have at least one aryl group (aryl group bonded to the boron atom, arylboron skeleton), particularly at least one aryl group having at least one halogen atom (fluoroaryl group).

The halogen atom is preferably chlorine or fluorine and is more preferably fluorine.

Among the above embodiments, it is more preferable that the anionic moiety has at least one aryl group having at least three halogen atoms, and it is even more preferable that the anionic moiety has at least one aryl group having at least five halogen atoms. In these embodiments, the Lewis acid strength and the polymerization initiating capability tend to be greater.

In the aryl group having at least one halogen atom, the halogen atom may be directly bonded to the aryl group, a halogen atom-containing group may be bonded to the aryl group, and these bonding modes may be used in combination.

Examples of the halogen atom-containing group include halogen-containing hydrocarbon groups [for example, haloalkyl groups (including halo-C₁₋₂₀ alkyl groups such as a trifluoromethyl group, a pentafluoroethyl group, a heptafluoropropyl group, and a perfluorooctyl group, preferably fluoro-C₁₋₁₀ alkyl groups, more preferably fluoro-C₁₋₄ alkyl groups, typically perfluoroalkyl groups), halocycloalkyl groups (including halo-C₃₋₂₀ cycloalkyl groups such as a perfluorocyclopropyl group, a perfluorocyclobutyl group, a perfluorocyclopentyl group, and a perfluorocyclohexyl group, preferably fluoro-C₄₋₈ cycloalkyl groups, typically perfluorocycloalkyl groups)], haloalkoxy groups (including halo-C₁₋₂₀ alkoxy groups such as a trifluoromethoxy group, a pentafluoroethoxy group, a heptafluoropropoxy group, and a perfluorooctoxy group, preferably fluoro-C₁₋₁₀ alkoxy groups, more preferably fluoro-C₁₋₄ alkoxy groups, typically perfluoroalkoxy groups), and halogenated sulfanyl groups (including a pentafluorosulfanyl group (—SF₅)).

Specific examples of the aryl group having at least one halogen atom (particularly fluorine atom) include fluoroaryl groups [for example, a pentafluorophenyl group, a 2-fluorophenyl group, a 2,3-difluorophenyl group, a 2,4-difluorophenyl group, a 2,5-difluorophenyl group, a 2,6-difluorophenyl group, a 3,5-difluorophenyl group, a 2,3,6-trifluorophenyl group, a 2,4,6-trifluorophenyl group, a 2,3,4,6-tetrafluorophenyl group, a 2,3,5,6-tetrafluorophenyl group, and a 2,2′,3,3′,4,4′,5,5′,6-nonafluoro-1,1′-biphenyl group, preferably a pentafluorophenyl group, a 2,6-difluorophenyl group, a 2,4,6-trifluorophenyl group, a 2,3,5,6-tetrafluorophenyl group, and a 2,2′,3,3′,4,4′,5,5′,6-nonafluoro-1,1′-biphenyl group], (fluoroalkyl)aryl groups [for example, a 2-trifluoromethylphenyl group, a 3-trifluoromethylphenyl group, a 4-trifluoromethylphenyl group, a 2-pentafluoroethylphenyl group, a 3-pentafluoroethylphenyl group, a 4-pentafluoroethylphenyl group, a 2,4-bis(trifluoromethyl)phenyl group, a 2,5-bis(trifluoromethyl)phenyl group, a 2,6-bis(trifluoromethyl)phenyl group, a 3,5-bis(trifluoromethyl)phenyl group, a 2,4,6-tris(trifluoromethyl)phenyl group, and a 2,4,6-trimethylphenyl group, preferably a 2,6-bis(trifluoromethyl)phenyl group, a 3,5-bis(trifluoromethyl)phenyl group, and a 2,4,6-tris(trifluoromethyl)phenyl group], fluoro-(fluoroalkyl)aryl groups [for example, fluoro-(fluoro-C₁₋₂₀ alkyl)-C₆₋₁₀ aryl groups such as a fluoro-trifluoromethylphenyl group (—C₆H₃FCF₃), a fluoro-bis(trifluoromethyl)phenyl group (—C₆H₂F(CF₃)₂), a fluoro-pentafluoroethylphenyl group (—C₆H₃FCF₃CF₂), and a fluoro-bis(pentafluoroethyl)phenyl group (—C₆H₂F(CF₃CF₂)₂), preferably fluoro-(fluoro-C₁₋₁₀ alkyl)-C₆₋₁₀ aryl groups, more preferably fluoro-(fluoro-C₁₋₄ alkyl)phenyl groups, typically fluoro-perfluoroalkylaryl groups], chloroaryl groups [for example, a pentachlorophenyl group, a 2-chlorophenyl group, a 2,3-dichlorophenyl group, a 2,4-dichlorophenyl group, a 2,5-dichlorophenyl group, a 2,6-dichlorophenyl group, a 3,5-dichlorophenyl group, a 2,3,6-trichlorophenyl group, a 2,4,6-trichlorophenyl group, a 2,3,4,6-tetrachlorophenyl group, and a 2,3,5,6-tetrachlorophenyl group, preferably a pentachlorophenyl group, a 2,6-dichlorophenyl group, and a 2,4,6-trichlorophenyl group], and (fluorosulfanyl)aryl groups [for example, a 2-pentafluorosulfanylphenyl group, a 3-pentafluorosulfanylphenyl group, a 4-pentafluorosulfanylphenyl group, a 2,4-bis(pentafluorosulfanyl)phenyl group, a 2,5-bis(pentafluorosulfanyl)phenyl group, a 2,6-bis(pentafluorosulfanyl)phenyl group, a 3,5-bis(pentafluorosulfanyl)phenyl group, a 2,4,6-tris(pentafluorosulfanyl)phenyl group, and a 2,4,6-trimethylphenyl group, preferably a 2,6-bis(pentafluorosulfanyl)phenyl group, a 3,5-bis(pentafluorosulfanyl)phenyl group, and a 2,4,6-tris(pentafluorosulfanyl)phenyl group].

Among these examples, particularly preferred are a pentafluorophenyl group, a 2,6-difluorophenyl group, a 2,4,6-trifluorophenyl group, a 2,3,5,6-tetrafluorophenyl group, a 2,2′,3,3′,4,4′,5,5′,6-nonafluoro-1,1′-biphenyl group, a pentachlorophenyl group, a 2,6-dichlorophenyl group, a 2,4,6-trichlorophenyl group, a 2-trifluoromethylphenyl group, a 2,6-bis(trifluoromethyl)phenyl group, a 3,5-bis(trifluoromethyl)phenyl group, a 2,4,6-tris(trifluoromethyl)phenyl group, and the like.

When the anionic moiety has at least one aryl group (aryl group bonded to the boron atom), the number of aryl groups may be 4 (the valence of a boron anion) or less, preferably 1 to 4, more preferably 2 or 3, and particularly preferably 3.

When the anionic moiety particularly has at least one aryl group (aryl group bonded to the boron atom) having at least one halogen atom (particularly fluorine atom), the number of aryl groups having at least one halogen atom is 1 to 3, preferably 2 or 3, and particularly preferably 3.

The anionic moiety (borate anion) is preferably represented by Formula (1).

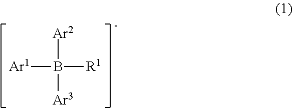

(In the formula, Ar¹, Ar², and Ar³ may be the same or different and each represent an aryl group optionally having a substituent; and R¹ represents a substituent)

In Ar¹, Ar², and Ar³ (aryl groups optionally having a substituent) of Formula (1), examples of the aryl group and the substituent include the aforementioned exemplary aryl groups and substituents.

In preferred embodiments, at least one (preferably two or three, more preferably three) of Ar¹, Ar², and Ar³ may be an aryl group having at least one halogen atom [for example, the aforementioned exemplary groups, such as a fluorophenyl group, a chlorophenyl group, a (fluoroalkyl)phenyl group, and a fluoro-(fluoroalkyl)phenyl group].

Among the above embodiments, it is more preferable that at least two of Ar¹, Ar², and Ar³ are aryl groups each having at least one halogen atom, and it is even more preferable that all three of Ar¹, Ar², and Ar³ are aryl groups each having at least one halogen atom. In these embodiments, the Lewis acid strength and the polymerization initiating capability tend to be greater.

Ar¹, Ar², and Ar³ may be the same or different. For example, when all of Ar¹, Ar², and Ar³ are aryl groups each having at least one fluorine atom, they may be aryl groups having the same number of fluorine atoms (for example, pentafluorophenyl groups) or a combination of aryl groups having different numbers of fluorine atoms.

In Formula (1), examples of R¹ (substituent) include the aforementioned exemplary substituents. Typical examples of the substituent include hydrocarbon groups, heterocyclic groups, and a hydroxy group.

R¹ is preferably an optionally substituted hydrocarbon group or a hydroxyl group and is particularly preferably an optionally substituted hydrocarbon group. In these embodiments, Lewis acid generation tends to be more efficient.

In the optionally substituted hydrocarbon group, examples of the substituent and the hydrocarbon group include the aforementioned exemplary groups.

Typical examples of R¹ include alkyl groups (for example, C₁₋₂₀ alkyl groups such as a methyl group, an ethyl group, a propyl group, and a butyl group, preferably C₁₋₁₀ alkyl groups, more preferably C₂₋₆ alkyl groups), aralkyl groups (for example, C₆₋₁₀ aryl-C₁₋₄ alkyl groups such as a benzyl group and a phenethyl group), and aryl groups (for example, C₆₋₁₀ aryl groups such as a phenyl group and a tolyl group). In particular, R¹ is preferably an aliphatic hydrocarbon group such as an alkyl group and an aralkyl group.

The compound of the present invention can generate a Lewis acid from the anionic moiety in response to light irradiation. Such a Lewis acid varies depending on the structure of the anionic moiety or the like, but is typically a compound derived from the anionic moiety by elimination of one of the four substituents bonded to boron (four substituents bonded to the central boron atom).

For example, in the case where the anionic moiety is represented by Formula (1), the Lewis acid to be generated is a compound derived from the anionic moiety by elimination of any one of Ar¹, Ar², Ar³ and R¹.

Specifically, by elimination of R¹, the compound represented by the following formula (for example, tris(pentafluorophenyl)borane (the compound in which Ar¹, Ar², and Ar³ are all pentafluorophenyl groups)) is generated as a Lewis acid.

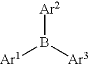

(In the formula, Ar¹, Ar², and Ar³ are the same as above)

The compound of the present invention, which can generate a Lewis acid derived from the anionic moiety having a central boron atom in response to light irradiation, can even generate a strong Lewis acid (for example, a fluoroarylborane such as tris(pentafluorophenyl)borane) due to such an anionic moiety.

Inorganic anions such as SbF₆⁻ and BF₄⁻ have the problem of generating a corrosive HF gas, and an organic anion (C₆F₅)₄B⁻ has the problem of discoloring or degrading a resin at high temperatures, but in the present invention, generation of such a HF gas or discoloration or degradation of a resin can be suppressed.

### Cationic Moiety

The cationic moiety is the counter cation of the anionic moiety and may be any cation that allows generation of a Lewis acid from the anionic moiety when combined with the anionic moiety.

In most cases, the generation of a Lewis acid involves charge transfer from an anion to a cation under light irradiation and subsequent elimination of a substituent as described above.

Therefore, the cationic moiety is preferably a moiety that readily allows light-induced charge (electron) transfer from the anionic moiety, resulting in immediate substituent elimination from the anionic moiety (facilitation of substituent elimination).

From these viewpoints, the cationic moiety may be a cation having a relatively low HOMO-LUMO gap (energy difference), and is for example, a cation having a HOMO-LUMO gap of 5.5 eV or less (for example, 5.3 eV or less), preferably 5.2 eV or less (for example, 5.1 eV or less), more preferably 5 eV or less (for example, 4.5 eV or less), and even more preferably 4.2 eV or less.

The lower limit of the gap is not particularly specified and may be, for example, 1 eV, 1.5 eV, or 2 eV.

The cationic moiety is preferably unreactive with a Lewis acid (a Lewis acid from the anionic moiety). A combination of such an unreactive cationic moiety with the anionic moiety enables efficient use of the Lewis acid to be generated from the anionic moiety.

Exemplary cationic moieties reactive with a Lewis acid include cationic moieties having a basic substituent that forms a salt with a Lewis acid and thus compromises the catalytic ability (for example, an amino group, an N-mono-substituted amino group, and an imino group (—NH—)). Therefore, the cationic moiety is preferably a cationic moiety not having a group that forms a salt with a Lewis acid.

The cationic moiety is preferably a cation that does not interfere (hardly interfere) with the generation of a Lewis acid from the anionic moiety. Specifically, the cationic moiety may be a cationic moiety (structure) that does not generate a protonic acid in response to light and/or a cationic moiety (structure) that does not degrade in response to light.

The central atom (cationic atom) of the cationic moiety is not particularly limited, and may be a sulfur atom (S), an iodine atom (I), or the like. In particular, the central atom may be a hetero atom selected from nitrogen, oxygen, and phosphorus, more particularly nitrogen and/or oxygen. The cationic moiety having such a hetero atom as the central atom typically does not interfere with the generation of a Lewis acid (for example, does not degrade in response to light) and contributes to efficient generation of a Lewis acid.

In the cationic moiety having a hetero atom as the central atom, the hetero atom may be in any structure without particular limitation, and may be a component of a chain structure or a cyclic structure. In particular, the hetero atom may be a component of a heterocycle (hetero ring). In other words, the cationic moiety having a hetero atom as the central atom may be (a cation of) a heterocycle or a hetero ring having, as a ring atom, at least one hetero atom selected from nitrogen, oxygen, and phosphorus. That is, the cationic moiety preferably comprises a hetero ring. In these embodiments, the polymerization initiating capability tends to be greater.

Such a hetero ring may be either an aliphatic ring or an aromatic ring, particularly an aromatic ring (aromatic heterocycle).

Specific examples of the hetero ring include nitrogen-containing heterocycles [for example, nitrogen-containing heterocycles (particularly nitrogen-containing aromatic heterocycles) including monocyclic rings (such as a pyridine ring (pyridinium ring)), polycyclic rings (for example, condensed rings such as a quinoline ring, an isoquinoline ring, and an indole ring; and ring assemblies such as a bipyridinium ring)], and oxygen-containing heterocycles [for example, oxygen-containing aromatic heterocycles such as a pyrylium ring (pyrylinium ring)].

It is preferable that no hydrogen atom (protonic hydrogen atom) is attached (bonded) to the hetero atom. For example, all the hydrogen atoms of an onium ion (for example, pyridinium (cation)) are preferably substituted by substituents other than a hydrogen atom.

Examples of the substituent attached (bonded) to the hetero atom include the exemplary substituents described in the section of the anionic moiety. Typical examples of the substituent include hydrocarbon groups [for example, optionally substituted hydrocarbon groups, including alkyl groups (for example, C₁₋₂₀ alkyl groups such as a methyl group, an ethyl group, a propyl group, a butyl group, a pentyl group, a hexyl group, a heptyl group, an octyl group, a nonyl group, and a decyl group, preferably C₁₋₁₀ alkyl groups), cycloalkyl groups (for example, C₃₋₂₀ cycloalkyl groups such as a cyclopentyl group and a cyclohexyl group, preferably C₄₋₈ cycloalkyl groups), aralkyl groups (for example, C₆₋₁₀ aryl-C₁₋₄ alkyl groups such as a benzyl group and a phenethyl group), and aryl groups (for example, C₆₋₁₀ aryl groups such as a phenyl group)].

In the cationic moiety, the hetero ring may have a substituent. The substituent attached (bonded) to the hetero ring can be selected as appropriate in light of the HOMO-LUMO gap and the like, and examples include the exemplary substituents described in the section of the anionic moiety (for example, hydrocarbon groups (including optionally substituted hydrocarbon groups, such as alkyl groups and aryl groups), and acyl groups (including C₁₋₁₀ alkylcarbonyl groups such as an acetyl group; and C₆₋₁₀ arylcarbonyl groups (aroyl groups) such as a benzoyl group)). The substituent may be a substituted or unsubstituted hetero ring.

A single substituent or a combination of two or more substituents may be bonded to the hetero ring.

Typical examples of the cationic moiety include cations having a nitrogen atom-containing heterocyclic skeleton [for example, a skeleton having a substituent on the nitrogen atom of any of the aforementioned exemplary nitrogen-containing heterocycles, such as an N-substituted pyridinium skeleton, an N-substituted bipyridinium skeleton, an N-substituted quinolinium skeleton, and an N-substituted isoquinolinium skeleton] {for example, N-substituted pyridiniums [including N-substituted arylpyridiniums (for example, N-substituted C₆₋₁₀ arylpyridiniums such as 4-phenyl-1-n-propylpyridinium, 4-phenyl-1-n-butylpyridinium, and 4-phenyl-1-benzylpyridinium, preferably N-alkyl-C₆₋₁₀ arylpyridiniums and N-aralkyl-C₆₋₁₀ arylpyridiniums, more preferably N—C₁₋₂₀ alkyl-phenylpyridiniums and N—C₆₋₁₀ aryl-C₁₋₄ alkyl-phenylpyridiniums), and N-substituted acylpyridiniums (for example, N-substituted C₆₋₁₀ arylcarbonylpyridiniums such as 4-benzoyl-1-benzylpyridinium)], N-substituted bipyridiniums [for example, N-substituted bipyridiniums (for example, N,N′-dialkylbipyridiniums such as 1,1′-dioctyl-4,4′-bipyridinium, preferably N,N′-di-C₁₋₂₀ alkylbipyridiniums, more preferably N,N′-di-C₁₋₁₀ alkylbipyridiniums)], N-substituted quinoliniums [for example, N-substituted quinoliniums (for example, N-alkylquinoliniums such as 1-ethylquinolinium, preferably N—C₁₋₂₀ alkyl-quinoliniums; and N-aralkylquinoliniums such as 1-benzylquinolinium, preferably N—C₆₋₁₀ aryl-C₁₋₄ alkylquinoliniums)], and N-substituted isoquinoliniums [for example, N-substituted isoquinoliniums (for example, N-alkylisoquinoliniums such as 2-n-butylisoquinolinium, preferably N—C₁₋₂₀ alkylisoquinoliniums; and N-aralkylisoquinoliniums such as 2-benzylisoquinolinium, preferably N—C₆₋₁₀ aryl-C₁₋₄ alkylquinoliniums)]}, cations having an oxygen atom-containing heterocyclic skeleton (for example, a skeleton having any of the aforementioned exemplary oxygen-containing heterocycles, such as a pyrylium skeleton) {for example, pyryliums [including alkyl pyryliums (for example, C₁₋₂₀ alkylpyryliums such as 2,4,6-trimethylpyrylium, preferably C₁₋₁₀ alkylpyryliums, more preferably C₁₋₄ alkylpyryliums)]}, and quaternary phosphoniums [for example, tetranaphthylphosphonium, methyltrinaphthylphosphonium, and phenacyltriphenylphosphonium].

Preferably, the cationic moiety may have a skeleton selected from N-substituted pyridinium skeletons, N-substituted bipyridinium skeletons, N-substituted quinolinium skeletons, quaternary phosphonium skeletons, and pyrylium skeletons.

The compound of the present invention is a compound having an anionic moiety and a cationic moiety (or a compound as a salt formed from an anionic moiety and a cationic moiety). The combination of the anionic moiety and the cationic moiety is not particularly limited as long as the combination allows the generation of a Lewis acid induced by light. All the combinations of the above anionic moieties and cationic moieties are included.

The wavelength of the light that induces the generation of a Lewis acid is not particularly limited and can be selected as appropriate for the applications of the compound of the present invention and the like. For example, the wavelength may be about 1,000 nm or less (for example, 900 nm or less), preferably about 800 nm or less (for example, 750 nm or less), and more preferably about 650 nm or less (for example, 630 nm or less), may be 220 nm or more (for example, 230 nm or more), preferably 240 nm or more (for example, 245 nm or more), more preferably 250 nm or more (for example, 275 nm or more), and even more preferably 295 nm or more, and may be typically 240 to 700 nm.

The light that induces the generation of a Lewis acid may be light in an ultraviolet to near infrared light range. In general, the light that induces the generation of acids is in the ultraviolet range, but in the present invention, a Lewis acid can be efficiently generated under light even in the visible to near-infrared range. As described above, the compound of the present invention can efficiently generate a Lewis acid, but in a light shielded or light unexposed environment, the compound of the present invention hardly degrades or generates a Lewis acid, and good stability or storage stability is ensured.

The compound of the present invention can be produced by reacting an anionic moiety with a cationic moiety. The reaction (salt formation reaction) can be performed by the usual method. For example, a salt of the anionic moiety (for example, a sodium salt, a potassium salt, and a complex salt such as a sodium/dimethoxyethane salt) and a salt of the cationic moiety (for example, a salt with a halogen such as bromine) may be reacted in an appropriate solvent to produce the compound.

The anionic moiety and the cationic moiety can also be produced by the usual method, and a commercial product may be used if available.

### Applications of Compound and Composition

The compound of the present invention, which generates a Lewis acid in response to light (light energy), can be also called a photo Lewis acid generator. The compound (and the photo Lewis acid generator) of the present invention can be used in various applications that can utilize a Lewis acid, for example, as a polymerization initiator (a photoinitiator, a photo-latent initiator), a chemically amplified resist material, and the like.

The compound (photo Lewis acid generator) of the present invention can be particularly preferably used as a photoinitiator (preferably a cationic photoinitiator). In other words, the photoinitiator of the present invention comprises the compound of the present invention.

The photoinitiator of the present invention comprises at least the compound of the present invention and may further comprise another photoinitiator to the extent that it does not impair the advantageous effects of the present invention. The amount of the compound of the present invention in the photoinitiator may be, for example, at about 10 to 100% by mass. The photoinitiator of the present invention may further comprise the solvent and/or additive described later.

The compound (photo Lewis acid generator) of the present invention can constitute various compositions appropriate for applications. In other words, the composition of the present invention comprises the compound (or the generator), and additional components can be selected as appropriate for applications and the like.

For example, when the compound is used as a polymerization initiator, the composition of the present invention may comprise the compound and a polymerizable compound that polymerizes in the presence of a Lewis acid.

Examples of such a polymerizable compound include cation polymerizable compounds (for example, cyclic ethers (such as an epoxy compound and an oxetane compound), vinyl ethers, and nitrogen-containing monomers (such as N-vinylpyrrolidone and N-vinylcarbazole)). The polymerizable compound may be an oligomer.

A single polymerizable compound may be used, and also two or more polymerizable compounds may be used in combination.

The polymerizable compound may typically comprise at least one compound selected from the above cation polymerizable compounds.

The epoxy compound (cation polymerizable epoxy resin) is not particularly limited, and examples include aliphatic epoxy compounds (for example, polyglycidyl ethers of aliphatic polyols, such as hexanediol diglycidyl ether), alicyclic epoxy compounds [for example, epoxycycloalkanes (including cyclohexene oxide and 3′,4′-epoxycyclohexylmethyl 3,4-epoxycyclohexanecarboxylate)], and aromatic epoxy compounds [for example, glycidyl ethers of phenols (including phenol, bisphenol A, and phenol novolac)]. These compounds may be used singly or in combination.

Among these examples, alicyclic epoxy compounds and aromatic epoxy compounds, particularly, alicyclic epoxy compounds may be preferably used.

In the epoxy compound, the epoxy group may be a glycidyl ether type epoxy group, a glycidyl ester type epoxy group, an olefin oxidation (alicyclic) type epoxy group, or the like.

In the composition, the proportion of the compound (or the generator) may be, for example, about 0.001 to 20 parts by mass, preferably about 0.01 to 10 parts by mass, and more preferably about 0.1 to 5 parts by mass relative to 100 parts by mass of, for example, the polymerizable compound.

The composition may further comprise, as needed, a solvent [for example, common solvents including carbonates (such as ethylene carbonate, propylene carbonate, 1,2-butylene carbonate, dimethyl carbonate, and diethyl carbonate)] and/or an additive (such as a sensitizer, a pigment, a filler, an antistatic agent, a flame retardant, a defoaming agent, a stabilizer, and an antioxidant).

A single solvent may be used, and also two or more solvents may be used in combination. Similarly, a single additive may be used, and also two or more additives may be used in combination.

When the composition comprises a solvent, the solid content of the composition may be, for example, about 0.01 to 50% by mass and preferably about 0.1 to 30% by weight.

The composition may further comprise, as needed, an acid generator or polymerization initiator that is not categorized as the compound (photo Lewis acid generator) of the present invention (for example, a photo acid generator (a compound capable of generating a protonic acid in response to light, a photo protonic acid generator)).

The compound of the present invention is relatively stable as described above and can form a highly stable composition. Therefore, the present invention encompasses a storage method or a production method of the composition. In such methods, the composition may be stored or produced in a light shielded or light unexposed environment.

More specifically, the present invention encompasses the following methods (A) and (B) and the like.

(A) A method for storing the composition (for example, a composition at least comprising the compound of the present invention and a polymerizable compound) in a light shielded environment.

(B) A method for producing the composition, comprising mixing the compound of the present invention with another component (particularly, a composition at least comprising a polymerizable compound) in a light shielded environment.

In the storage method, the storage period is not particularly limited and may be, for example, 1 day or more, 3 days or more, 5 days or more, 10 days or more, 20 days or more, 30 days or more, or 50 days or more. The upper limit of the storage period is not particularly specified and may be, for example, 5 years, 4 years, 3 years, 2 years, 1 year, 6 months, or 3 months.

In the light shielded environment, it is at least necessary to shield the light that induces the generation of a Lewis acid from the compound (the light in a wavelength range that is absorbed by the compound). The degree of light shielding may be, for example, in terms of light transmission rate at the above wavelength or in the above wavelength range, 20% or less, preferably 10% or less, more preferably 5% or less, and particularly preferably 3% or less.

In the storage method and the production method, the temperature during storing or mixing is not particularly limited and may be a low temperature (for example, 10° C. or less), an ordinary temperature (for example, 10 to 35° C.), or a heated temperature (for example, 35° C. or more). In the present invention, even at a relatively high temperature (for example, 20 to 80° C., 25 to 70° C., 30 to 60° C., or 35 to 50° C.), high stability can be ensured.

The light shielding method is not particularly limited as long as a light shielded environment can be provided during storing or mixing. For example, storing or mixing in the dark, storing the composition in a light resistant container, and a combination of these methods are available.

The compound of the present invention generates a Lewis acid in response to light as described above. Therefore, the present invention also encompasses a method for generating a Lewis acid, the method comprising light irradiation of (irradiation of active energy rays to) the composition (the compound or the generator) of the present invention.

When this method is employed on the composition comprising a polymerizable compound, the generated Lewis acid promotes polymerization of the polymerizable compound, and a polymer of the polymerizable compound can be produced. Therefore, the present invention also encompasses a method for producing a polymer from a polymerizable compound that polymerizes in the presence of a Lewis acid, the method comprising light irradiation of the composition comprising the polymerizable compound.

In the case where some types of polymerizable compounds are used, the resulting polymer is a cured product.

The light source used for the light irradiation is not particularly limited as long as it is suitable for the generation of a Lewis acid, and examples include a fluorescent lamp, a mercury lamp (low-pressure, medium-pressure, high-pressure, ultrahigh-pressure, or the like), a metal halide lamp, an LED lamp, a xenon lamp, a carbon arc lamp, a laser (for example, a semiconductor solid-state laser, an argon laser, a He—Cd laser, a KrF excimer laser, an ArF excimer laser, and a F2 laser). In the present invention, even a visible light source (LED lamp) can be used.

The light irradiation time can be selected as appropriate for the types of the compound, the polymerizable compound, the light source, and the like and is not particularly limited.

The polymer production method may be performed under heat. When performed under heat, the method can achieve more efficient polymerization (curing).

The heating (heating step) may be performed before light irradiation, during light irradiation (simultaneous with light irradiation), or after light irradiation, or any combination of these timings as long as the composition or the compound can be heated. Typically, the heating may be performed during light irradiation and/or after light irradiation, particularly at least during light irradiation or in light irradiation.

The heating temperature is not particularly limited, may be, for example, 35° C. or more (for example, 35 to 150° C.), 40° C. or more (for example, 40 to 120° C.), or 45° C. or more (for example, 45 to 100° C.), and may be 50° C. or more (for example, 50 to 80° C.), 60° C. or more, 70° C. or more, or the like.

Examples of the application of the composition of the present invention include a paint, a coating agent, various covering materials (such as a hard coating, a stain resistant coating material, an antifog coating material, an anti-corrosion coating material, and an optical fiber), a back coating agent for adhesive tapes, a releasable coating material of a release sheet (such as a release paper, a release plastic film, and a release metal foil) for adhesive labels, a printing board, an ink for dental materials (a dental compound, a dental composite), an ink for ink jet printing, a positive resist (for formation of connecting terminals and wiring patterns in the production of electronic components such as circuit boards, CSPs, and MEMS elements), a resist film, a liquid resist, a negative resist (for example, a permanent film material for surface protective films, interlayer insulation films, planarizing films, and the like of semiconductor devices), a resist for MEMS, a positive photosensitive material, a negative photosensitive material, various adhesives (such as a temporary fixing agent for various electronic components, an adhesive for HDDs, an adhesive for pickup lenses, and an adhesive for FPD functional films (for example, deflecting plates and anti-reflective coatings)), a hologram resin, a FPD material (for example, a color filter, a black matrix, a partition material, a photo spacer, a rib, a liquid crystal alignment film, and a FPD sealing material), an anisotropic conductive material, an optical member, a molding material (for building materials, optical components, and lenses), a casting material, a putty, a glass fiber impregnant, a filler, a sealing material, a sealer, a sealer for optical semiconductors (LEDs), an optical waveguide material, a nanoimprint material, a lithographic material, and a microlithographic material.

The present invention is not limited to the above embodiments, and various modifications can be made. Embodiments obtained by appropriately combining technical means disclosed in different embodiments herein are also encompassed in the technical scope of the present invention.

### EXAMPLES

Hereinafter, the present invention will be described in further detail with reference to examples, but the present invention is not intended to be limited by the examples shown below. Various modifications can be made without departing from the gist of the invention as described above and below and are encompassed in the technical scope of the present invention.

### Synthesis Example 1 Production of Pentafluorophenyl Magnesium Bromide

Magnesium (2.64 g, 0.109 mol) was placed into a reaction container with a thermometer, a dropping funnel, a stirrer, a nitrogen inlet tube, and a reflux condenser, the headspace was thoroughly replaced with nitrogen gas, and dibutyl ether (52.3 g) was placed into the reaction container. n-Butyl bromide (13.4 g, 0.098 mol) was placed into the dropping funnel.

The n-butyl bromide was added dropwise from the dropping funnel at a temperature not higher than 30° C. to give a dibutyl ether solution of n-butyl magnesium bromide.

Bromopentafluorobenzene (25.3 g, 0.103 mol) was placed into the dropping funnel. To the solution obtained by the above reaction, the bromopentafluorobenzene was added dropwise from the dropping funnel at a temperature not higher than 30° C. to give a dibutyl ether solution of pentafluorophenyl magnesium bromide.

F-NMR analysis confirmed that pentafluorophenyl magnesium bromide (the compound shown below) was obtained. The conversion rate of bromopentafluorobenzene was 97% or more.

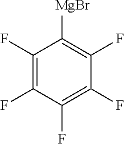

### Synthesis Example 2 Production of tris(pentafluorophenyl)borane

The same reaction container as used in Synthesis Example 1 was prepared, and the headspace was thoroughly replaced with nitrogen gas. Boron trifluoride tetrahydrofuran complex (4.70 g, 0.034 mol) as a boron compound and methylcyclohexane (17.0 g) were placed into the reaction container. The dibutyl ether solution containing pentafluorophenyl magnesium bromide obtained in Synthesis Example 1 was placed into a dropping funnel.

The dibutyl ether solution was added dropwise to the reaction container at a temperature not higher than 30° C. over 30 minutes, and the reaction mixture was stirred at room temperature for another 2 hours. Consequently, a dibutyl ether solution of tris(pentafluorophenyl)borane was obtained.

F-NMR analysis confirmed that tris(pentafluorophenyl)borane (the following compound) was obtained.

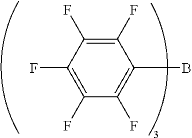

### Synthesis Example 3 Production of Sodium n-butyl-tris(pentafluorophenyl)borate/dimethoxyethane Complex

The same reaction container as used in Synthesis Example 1 was prepared, and the headspace was thoroughly replaced with nitrogen gas. A dibutyl ether solution containing n-butyl magnesium bromide prepared in the same manner as in Synthesis Example 1 was placed into the reaction container. The dibutyl ether solution containing tris(pentafluorophenyl)borane prepared in Synthesis Example 2 was placed into a dropping funnel.

The dibutyl ether solution in the dropping funnel was added dropwise to the dibutyl ether solution in the reaction container with stirring at a temperature not higher than 30° C. over 15 minutes. The reaction mixture was heated to 50° C. and stirred for another 3 hours. Consequently, n-butyl-tris(pentafluorophenyl)borate magnesium bromide was obtained as a dibutyl ether solution.

An excess amount of aqueous hydrochloric acid solution was added, and the whole was stirred for 15 minutes. The reaction mixture was allowed to stand until separation into two layers, and the aqueous layer was removed. To the organic layer in the reaction container, an aqueous solution of 1.20 g of sodium carbonate in 18 g of water was added, and the whole was stirred for 15 minutes. The reaction mixture was allowed to stand until separation into two layers, and the aqueous layer was removed. Consequently, a dibutyl ether solution of a sodium salt of n-butyl-tris(pentafluorophenyl)borate was obtained.

To the dibutyl ether solution, dimethoxyethane (4.56 g, 0.051 mol) was added, and the mixture was stirred to give a crystalline precipitate of sodium n-butyl-tris(pentafluorophenyl)borate/dimethoxyethane complex. The crystalline precipitate was collected by filtration, washed with heptane, and air-dried, giving 11.8 g of sodium n-butyl-tris(pentafluorophenyl)borate/dimethoxyethane complex as crystals.

H-NMR and F-NMR analysis confirmed that sodium n-butyl-tris(pentafluorophenyl)borate/dimethoxyethane complex (the following compound) was obtained.

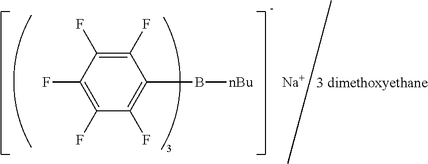

### Example 1 Production of 1,1′-diheptyl-4,4′-bipyridinium n-butyl-tris(pentafluorophenyl)borate

The same reaction container as used in Synthesis Example 1 was prepared, and the headspace was thoroughly replaced with nitrogen gas. The sodium n-butyl-tris(pentafluorophenyl)borate/dimethoxyethane (0.149 g, 0.17 mmol) obtained in Synthesis Example 3, ethyl acetate (3.9 g), and water (4.0 g) were placed into the reaction container. 1,1′-Dioctyl-4,4′-bipyridinium bromide (0.089 g, 0.17 mmol) was weighed and added to the reaction container.

The whole was stirred at room temperature for another 1 hour. The reaction mixture was allowed to stand until separation into two layers, and the aqueous layer at the bottom was removed. Water (5.0 g) was added to the organic layer, and the whole was stirred, washed, and allowed to stand. The aqueous layer at the bottom was removed. Consequently, an ethyl acetate solution containing 1,1′-diheptyl-4,4′-bipyridinium n-butyl-tris(pentafluorophenyl)borate was obtained. The solution was dehydrated and dried over anhydrous magnesium carbonate. The ethyl acetate was removed with an evaporator to yield 1,1′-diheptyl-4,4′-bipyridinium n-butyl-tris(pentafluorophenyl)borate as a solid (0.21 g).

H-NMR and F-NMR analysis confirmed that 1,1′-diheptyl-4,4′-bipyridinium n-butyl-tris(pentafluorophenyl)borate (the following compound) was obtained.

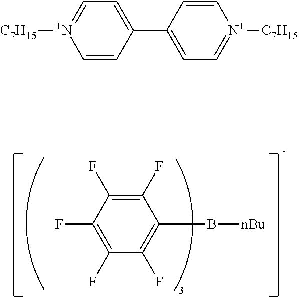

### Synthesis Example 4 Production of sodium ethyl-tris(pentafluorophenyl)borate/dimethoxyethane Complex

The same procedure as in Synthesis Example 1 was performed except that n-butyl bromide was changed to ethyl bromide, giving ethyl magnesium bromide.

The same procedure as in Synthesis Example 3 was performed except that n-butyl magnesium bromide was changed to the ethyl magnesium bromide obtained by the above reaction, giving sodium ethyl-tris(pentafluorophenyl)borate/dimethoxyethane complex as crystals.

H-NMR and F-NMR analysis confirmed that sodium ethyl-tris(pentafluorophenyl)borate/dimethoxyethane complex (the following compound) was obtained.

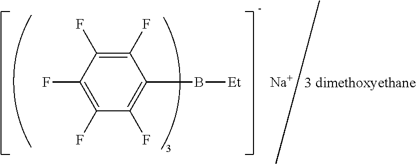

### Synthesis Example 5 Production of Sodium benzyl-tris(pentafluorophenyl)borate/dimethoxyethane Complex

The same procedure as in Synthesis Example 1 was performed except that n-butyl bromide was changed to benzyl bromide, giving benzyl magnesium bromide.

The same procedure as in Synthesis Example 3 was performed except that n-butyl magnesium bromide was changed to the benzyl magnesium bromide obtained by the above reaction, giving sodium benzyl-tris(pentafluorophenyl)borate/dimethoxyethane complex as crystals.

H-NMR and F-NMR analysis confirmed that sodium benzyl-tris(pentafluorophenyl)borate/dimethoxyethane complex (the following compound) was obtained.

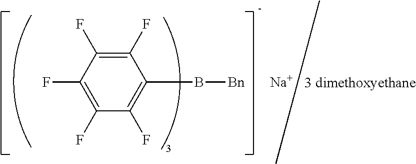

### Example 2 Production of 1,1′-diheptyl-4,4′-bipyridinium ethyl-tris(pentafluorophenyl)borate

The same procedure as in Example 1 was performed except that sodium n-butyl-tris(pentafluorophenyl)borate/dimethoxyethane complex was changed to sodium ethyl-tris(pentafluorophenyl)borate/dimethoxyethane complex, giving 1,1′-diheptyl-4,4′-bipyridinium ethyl-tris(pentafluorophenyl)borate as a solid.

H-NMR and F-NMR analysis confirmed that 1,1′-diheptyl-4,4′-bipyridinium ethyl-tris(pentafluorophenyl)borate (the following compound) was obtained.

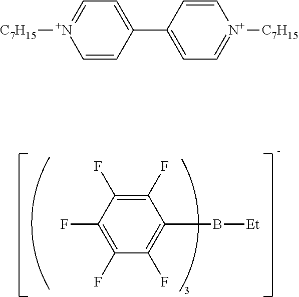

### Example 3 Production of 1,1′-diheptyl-4,4′-bipyridinium benzyl-tris(pentafluorophenyl)borate

The same procedure as in Example 1 was performed except that sodium n-butyl-tris(pentafluorophenyl)borate/dimethoxyethane complex was changed to sodium benzyl-tris(pentafluorophenyl)borate/dimethoxyethane complex, giving 1,1′-diheptyl-4,4′-bipyridinium benzyl-tris(pentafluorophenyl)borate as a solid.

H-NMR and F-NMR analysis confirmed that 1,1′-diheptyl-4,4′-bipyridinium benzyl-tris(pentafluorophenyl)borate (the following compound) was obtained.

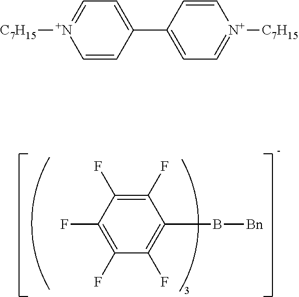

### Example 4 Production of 4-phenyl-1-n-propylpyridinium benzyl-tris(pentafluorophenyl)borate

The same procedure as in Example 3 was performed except that 1,1′-diheptyl-4,4′-bipyridinium dibromide was changed to 4-phenyl-1-n-propylpyridinium bromide, giving 4-phenyl-1-n-propylpyridinium benzyl-tris(pentafluorophenyl)borate as a solid.

H-NMR and F-NMR analysis confirmed that 4-phenyl-1-n-propylpyridinium benzyl-tris(pentafluorophenyl)borate (the following compound) was obtained.

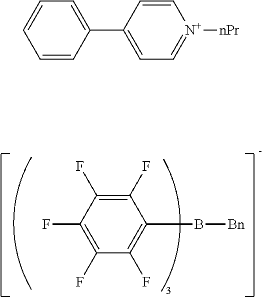

### Example 5 Production of 4-benzoyl-1-benzylpyridinium benzyl-tris(pentafluorophenyl)borate

The same procedure as in Example 1 was performed except for using 4-benzoyl-1-benzylpyridinium bromide and sodium benzyl-tris(pentafluorophenyl)borate/dimethoxyethane complex, giving 4-benzoyl-1-benzylpyridinium benzyl-tris(pentafluorophenyl)borate as a solid.

H-NMR and F-NMR analysis confirmed that 4-benzoyl-1-benzylpyridinium benzyl-tris(pentafluorophenyl)borate (the following compound) was obtained.

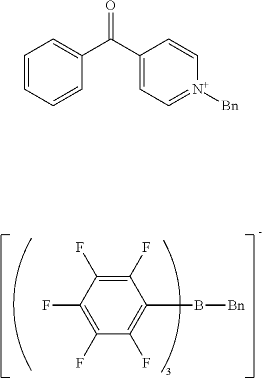

### Example 6 Production of 1-benzylquinolinium benzyl-tris(pentafluorophenyl)borate

The same procedure as in Example 1 was performed except for using 1-benzylquinolinium bromide and sodium benzyl-tris(pentafluorophenyl)borate/dimethoxyethane complex, giving 1-benzylquinolinium benzyl-tris(pentafluorophenyl)borate as a viscous liquid.

H-NMR and F-NMR analysis confirmed that 1-benzylquinolinium benzyl-tris(pentafluorophenyl)borate (the following compound) was obtained.

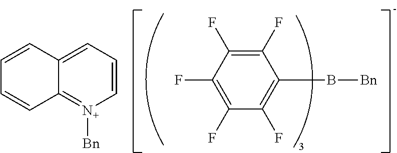

### Example 7 Production of 2,4,6-trimethylpyrylium benzyl-tris(pentafluorophenyl)borate

The same procedure as in Example 1 was performed except for using 2,4,6-trimethylpyrylium bromide and sodium benzyl-tris(pentafluorophenyl)borate/dimethoxyethane complex, giving 2,4,6-trimethylpyrylium benzyl-tris(pentafluorophenyl)borate as a solid.

H-NMR and F-NMR analysis confirmed that 2,4,6-trimethylpyrylium benzyl-tris(pentafluorophenyl)borate (the following compound) was obtained.

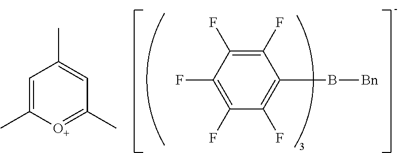

### Synthesis Example 6 Production of Pentafluorophenyl Magnesium Bromide

In a similar manner to that in Synthesis Example 1, magnesium (2.48 g, 0.102 mol) was placed into a reaction container with a thermometer, a dropping funnel, a stirrer, a nitrogen inlet tube, and a reflux condenser, the headspace was thoroughly replaced with nitrogen gas, and cyclopentyl methyl ether (37.8 g) was placed into the reaction container.

Bromopentafluorobenzene (21.0 g, 0.085 mol) was placed into the dropping funnel. About 2 g of the bromopentafluorobenzene was added dropwise from the dropping funnel at a temperature not higher than 30° C., and the whole was stirred for a while. During the stirring, the temperature of the reaction mixture increased, indicating the start of the reaction. The remaining bromopentafluorobenzene was added dropwise at a temperature not higher than 30° C. to give a cyclopentyl methyl ether solution of pentafluorophenyl magnesium bromide.

F-NMR analysis confirmed that pentafluorophenyl magnesium bromide (the compound shown below) was obtained. The conversion rate of bromopentafluorobenzene was 97% or more.

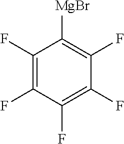

### Synthesis Example 7 Production of tris(pentafluorophenyl)borane

The same reaction container as used in Synthesis Example 1 was prepared, and the headspace was thoroughly replaced with nitrogen gas. The cyclopentyl methyl ether solution of pentafluorophenyl magnesium bromide prepared in Synthesis Example 6 was transferred to the reaction container while passed through a glass filter to remove unreacted magnesium metal. Boron trifluoride tetrahydrofuran complex (3.8 g, 0.0272 mol) was placed into a dropping funnel. The complex was added dropwise from the dropping funnel at a temperature not higher than 30° C. over 30 minutes, and the reaction mixture was stirred at room temperature for another 2 hours. Consequently, a cyclopentyl methyl ether solution of tris(pentafluorophenyl)borane was obtained.

The same reaction container as used in Synthesis Example 1 was separately prepared, and isododecane (200 g) was placed into the container. The cyclopentyl methyl ether solution of tris(pentafluorophenyl)borane obtained above was placed into a dropping funnel, and the dropping funnel was set to the reaction container containing isododecane. The cyclopentyl methyl ether solution of tris(pentafluorophenyl)borane was added dropwise at about 70° C. under reduced pressure to allow solvent exchange between cyclopentyl methyl ether and isododecane. A magnesium salt precipitate formed as a by-product in the reaction container was removed by filtration.

Consequently, an isododecane solution of tris(pentafluorophenyl)borane was obtained. To this, dibutyl ether (13.5 g) was added to prevent the precipitation of tris(pentafluorophenyl)borane due to drop in liquid temperature.

F-NMR analysis confirmed that tris(pentafluorophenyl)borane (the following compound) was obtained.

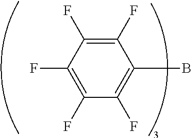

### Synthesis Example 8 Production of Aqueous Solution of Sodium n-butyl-tris(pentafluorophenyl)borate

The same reaction container as used in Synthesis Example 1 was prepared, and the headspace was thoroughly replaced with nitrogen gas. A dibutyl ether solution containing n-butyl magnesium bromide prepared the same manner as in Synthesis Example 1 was placed into the reaction container. The isododecane solution containing tris(pentafluorophenyl)borane obtained in Synthesis Example 7 was placed into a dropping funnel.

The isododecane solution in the dropping funnel was added dropwise to the dibutyl ether solution in the reaction container with stirring at a temperature not higher than 30° C. over 1 hour. The reaction mixture was heated to 50° C. and stirred for 1 hour. The reaction mixture was further heated to 70° C. and stirred for 2 hours. Consequently, a reaction solution of n-butyl-tris(pentafluorophenyl)borate magnesium bromide was obtained.

An excess amount of aqueous hydrochloric acid solution was added, and the whole was stirred for 15 minutes. The reaction mixture was allowed to stand until separation into two layers, and the aqueous layer was removed. To the organic layer in the reaction container, an aqueous solution of sodium carbonate (2.7 g, 0.026 mol) in 18.0 g of water was added, and the whole was stirred for 15 minutes. The reaction mixture was allowed to stand until separation into two layers, and the aqueous layer was removed. Consequently, an isododecane solution of a sodium salt of n-butyl-tris(pentafluorophenyl)borate was obtained.

To the isododecane solution, water (160 g) was added, and the organic solvent was evaporated off together with water under reduced pressure, giving an aqueous solution of a sodium salt of n-butyl-tris(pentafluorophenyl)borate (84.0 g, a borate solid content: 14.7% by mass).

H-NMR and F-NMR analysis confirmed that an aqueous solution of sodium n-butyl-tris(pentafluorophenyl)borate was obtained.

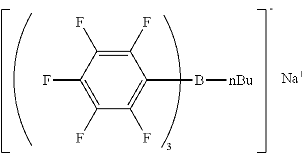

### Synthesis Example 9 Production of Aqueous Solution of Sodium benzyl-tris(pentafluorophenyl)borate

The same procedure as in Synthesis Example 1 was performed except that n-butyl bromide was changed to benzyl bromide, giving benzyl magnesium bromide.

The same procedure as in Synthesis Example 8 was performed except that n-butyl magnesium bromide was changed to the benzyl magnesium bromide obtained by the above reaction, giving an aqueous solution of a sodium salt of benzyl-tris(pentafluorophenyl)borate.

H-NMR and F-NMR analysis confirmed that an aqueous solution of sodium benzyl-tris(pentafluorophenyl)borate was obtained.

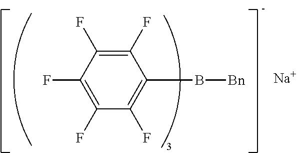

### Example 8 Production of 4-phenyl-1-n-butylpyridinium n-butyl-tris(pentafluorophenyl)borate

4-Phenyl-1-n-butylpyridinium bromide (0.125 g, 0.42 mmol) was placed into a pear-shaped flask with a stirrer, and water (0.56 g) was added to prepare an aqueous solution. The aqueous solution of sodium n-butyl-tris(pentafluorophenyl)borate (1.70 g, a borate solid content: 14.7% by mass) obtained in Synthesis Example 8 was added dropwise at 0° C. with stirring.

Stirring was continued for 1 hour, and the mixture was heated to 50° C. and stirred for 1 hour. During the dropwise addition, a white solid precipitate was formed. The solid was collected by filtration, washed with a small amount of water, and dried, giving 4-phenyl-1-n-butylpyridinium n-butyl-tris(pentafluorophenyl)borate as a white solid (0.31 g).

H-NMR and F-NMR analysis confirmed that 4-phenyl-1-n-butylpyridinium n-butyl-tris(pentafluorophenyl)borate (the following compound) was obtained.

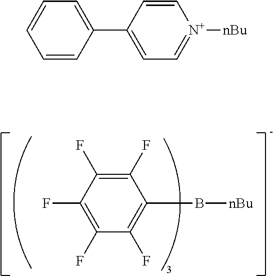

### Example 9 Production of 4-phenyl-1-n-butylpyridinium benzyl-tris(pentafluorophenyl)borate

The same procedure as in Example 8 was performed except that the aqueous solution of sodium n-butyl-tris(pentafluorophenyl)borate was changed to an aqueous solution of sodium benzyl-tris(pentafluorophenyl)borate, giving 4-phenyl-1-n-propylpyridinium benzyl-tris(pentafluorophenyl)borate as a solid.

H-NMR and F-NMR analysis confirmed that 4-phenyl-1-n-propylpyridinium benzyl-tris(pentafluorophenyl)borate (the following compound) was obtained.

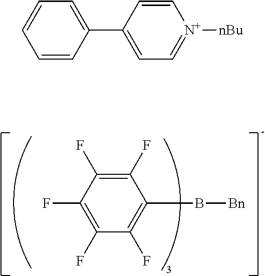

### Example 10 Production of 1-ethylquinolinium benzyl-tris(pentafluorophenyl)borate

The same procedure as in Example 8 was performed except that the aqueous solution of sodium n-butyl-tris(pentafluorophenyl)borate was changed to an aqueous solution of sodium benzyl-tris(pentafluorophenyl)borate and 4-phenyl-1-n-butylpyridinium bromide was changed to 1-ethylquinolinium bromide, giving 1-ethylquinolinium benzyl-tris(pentafluorophenyl)borate as a solid.

H-NMR and F-NMR analysis confirmed that 1-ethylquinolinium benzyl-tris(pentafluorophenyl)borate (the following compound) was obtained.

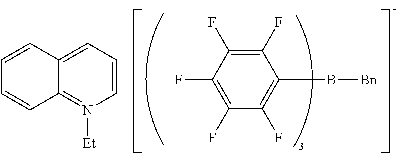

### Example 11 Production of 2-benzylisoquinolinium benzyl-tris(pentafluorophenyl)borate

The same procedure as in Example 8 was performed except that the aqueous solution of sodium n-butyl-tris(pentafluorophenyl)borate was changed to an aqueous solution of sodium benzyl-tris(pentafluorophenyl)borate and 4-phenyl-1-n-butylpyridinium bromide was changed to 2-benzylisoquinolinium bromide, giving 2-benzylisoquinolinium benzyl-tris(pentafluorophenyl)borate as a solid.

H-NMR and F-NMR analysis confirmed that 2-benzylisoquinolinium benzyl-tris(pentafluorophenyl)borate (the following compound) was obtained.

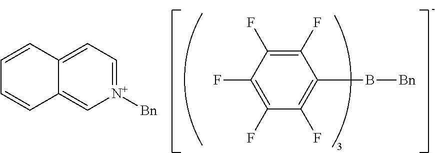

### Comparative Example 1 Production of Tetraphenylphosphonium benzyl-tris(pentafluorophenyl)borate

The same procedure as in Example 1 was performed except for using tetraphenylphosphonium bromide and sodium benzyl-tris(pentafluorophenyl)borate/dimethoxyethane complex, giving tetraphenylphosphonium benzyl-tris(pentafluorophenyl)borate as a viscous liquid.

H-NMR and F-NMR analysis confirmed that tetraphenylphosphonium benzyl-tris(pentafluorophenyl)borate (the following compound) was obtained.

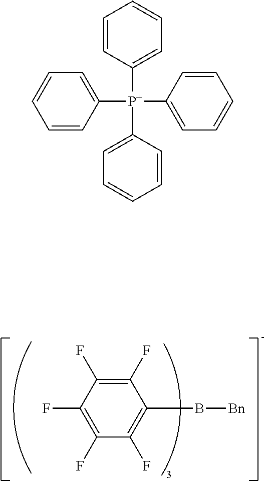

### Comparative Example 2 Production of tetra-n-butylammonium benzyl-tris(pentafluorophenyl)borate

The same procedure as in Example 1 was performed except for using tetra-n-butylammonium bromide and sodium benzyl-tris(pentafluorophenyl)borate/dimethoxyethane complex, giving tetra-n-butylammonium benzyl-tris(pentafluorophenyl)borate as a viscous liquid.

H-NMR and F-NMR analysis confirmed that tetra-n-butylammonium benzyl-tris(pentafluorophenyl)borate (the following compound) was obtained.

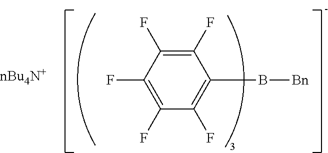

### Comparative Example 3 Production of 1-n-butylpyridinium benzyl-tris(pentafluorophenyl)borate

The same procedure as in Example 4 was performed except for using 1-n-butylpyridinium bromide and sodium benzyl-tris(pentafluorophenyl)borate/dimethoxyethane complex, giving 1-n-butylpyridinium benzyl-tris(pentafluorophenyl)borate as a viscous liquid.

H-NMR and F-NMR analysis confirmed that 1-n-butylpyridinium benzyl-tris(pentafluorophenyl)borate (the following compound) was obtained.

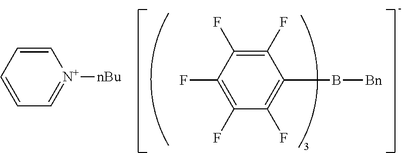

### Examination of Lewis Acid Generation

The compounds obtained in Examples and Comparative Examples were used to examine the generation of a Lewis acid.

First, 1 part by mass of each of the compounds obtained in Examples and Comparative Examples was dissolved in 1 part by mass of propylene carbonate. To the obtained solution (15 mg), UV light was irradiated with a high-pressure mercury lamp (irradiation intensity at a wavelength of 365 nm; 50 mW/cm²) for 5 minutes at 25° C.

The solution after light irradiation was analyzed by F-NMR for the generation of tris(pentafluorophenyl)borane as a Lewis acid.

### Evaluation of Polymerization Ability

The compounds obtained in Examples and Comparative Examples were used to perform a polymerization test.

First, 1 part by mass of each of the compounds obtained in Examples and Comparative Examples was dissolved in 1 part by mass of propylene carbonate. One part by mass of the solution was mixed with 99 parts by mass of a polymerizable compound (an alicyclic epoxy resin (Celloxide 2021P, manufactured by Daicel) or an aromatic epoxy resin (bisphenol A diglycidyl ether, manufactured by Tokyo Chemical Industry Co., Ltd.)).

For the compounds obtained in Examples 1 to 7 and Comparative Examples 1 to 3, the alicyclic epoxy resin was used, and for the compounds obtained in Examples 8 to 11, both the alicyclic epoxy resin and the aromatic epoxy resin were used.

To the obtained solution (5 mg), UV light was irradiated with a high-pressure mercury lamp (irradiation intensity at a wavelength of 365 nm; 20 mW/cm²) for 5 minutes at 25° C. (without heating), 50° C., or 80° C., and the heat generated by polymerization during the irradiation was measured with a photo-DSC. The amount of heat generated was defined as the area enclosed by the DSC exothermic peak corresponding to polymerization and a straight line drawn between the start and end time points of the light irradiation.

For the compounds obtained in Examples 1 to 7 and Comparative Examples 1 to 3, the measurement was performed only at 50° C.

### Calculation Method for HOMO-LUMO Gap of Cationic Moiety

The HOMO and LUMO energies of the compounds obtained in Examples and Comparative Examples were calculated with Gaussian 09, a software for molecular orbital calculation, manufactured by Gaussian, USA.

The calculation method used was the density functional theory B3LYP, and the basis set used was 6-311G(d,p). The molecular structure of the compound to be analyzed was optimized, and the HOMO/LUMO energy levels (in terms of eV unit) after the structure optimization were calculated.

The results are shown in Table 1, Table 2, Table 3, and Table 4 together with the structures of the compounds.

TABLE 1

| | | Exothermic | Amount of | HOMO-LUMO | Generation |
|---|---|---|---|---|---|
| | | peak time | heat generated | gap of cationic | of |
| | Compound | (min) | (mJ/mg) | moiety (ev) | Lewis acid |
| Example 1 | 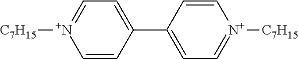 | 0.19 | 181 | 2.322 | Generated |
| | 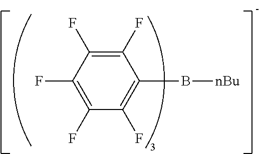 | | | | |
| Example 2 | 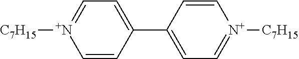 | 0.93 | 145 | | Generated |
| | 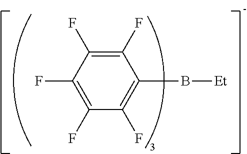 | | | | |
| Example 3 | 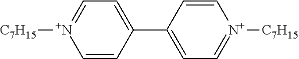 | 0.22 | 118 | | Generated |
| | 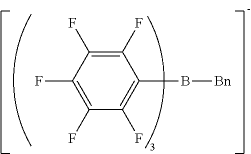 | | | | |
| Example 4 | 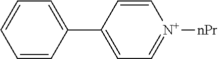 | 0.25 | 166 | 4.038 | Generated |
| | 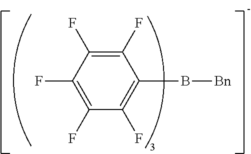 | | | | |
| Example 5 | 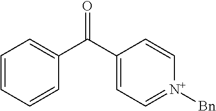 [SMILES: O=C(c1ccccc1)c1cc[n+](Cc2ccccc2)cc1] | 0.27 | 150 | 3.528 | Generated |
| | 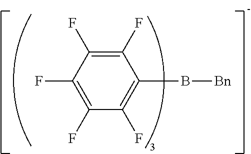 | | | | |
| Example 6 | 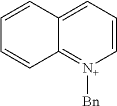 [SMILES: c1ccc(C[n+]2cccc3ccccc32)cc1] | 0.15 | 237 | 3.821 | Generated |
| | 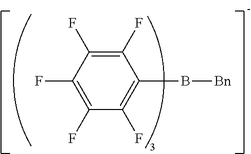 | | | | |
| Example 7 | 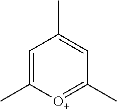 | 0.36 | 110 | 5.224 | Generated |
| | 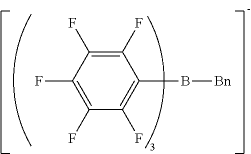 | | | | |

TABLE 2

| | | | Amount of | HOMO-LUMO | Generation |
|---|---|---|---|---|---|
| | | | heat generated | gap of cationic | of |
| | Compound | Exothermic peak time (min) | (mJ/mg) | moiety (ev) | Lewis acid |
| Example 8 | 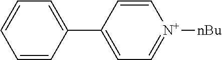 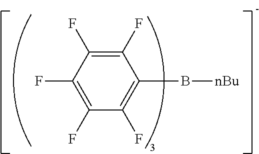 | 2.07 (alicyclic epoxy resin, at 25° C.) 0.27 (alicyclic epoxy resin, at 50° C.) no peak due to constant heat generation (aromatic epoxy resin, at 50° C.) 0.55 (aromatic epoxy resin, at 80° C.) | 189 237 128 380 | 4.046 | Generated |
| Example 9 | 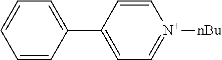 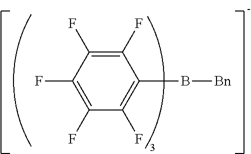 | 0.43 (alicyclic epoxy resin, at 25° C.) 0.28 (alicyclic epoxy resin, at 50° C.) 4.40 (aromatic epoxy resin, at 50° C.) 0.32 (aromatic epoxy resin, at 80° C.) | 216 247 151 409 | 4.046 | Generated |

TABLE 3

| | | | Amount of | HOMO-LUMO | Generation |
|---|---|---|---|---|---|
| | | | heat generated | gap of cationic | of |
| | Compound | Exothermic peak time (min) | (mJ/mg) | moiety (ev) | Lewis acid |
| Example 10 | 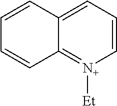 [SMILES: CC[n+]1cccc2ccccc21] 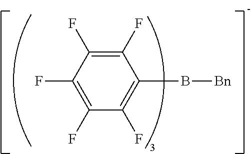 | 0.19 (alicyclic epoxy resin, at 25° C.) 0.17 (alicyclic epoxy resin, at 50° C.) No peak (aromatic epoxy resin, at 25° C.) 0.54 (aromatic epoxy resin, at 50° C.) 0.15 (aromatic epoxy resin, at 80° C.) | 280 322 140 400 419 | 4.321 | Generated |
| Example 11 | 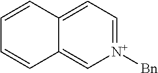 [SMILES: c1ccc(C[n+]2ccc3ccccc3c2)cc1] 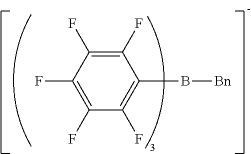 | 0.23 (alicyclic epoxy resin, at 25° C.) 0.16 (alicyclic epoxy resin, at 50° C.) 0.38 (aromatic epoxy resin, at 50° C.) 0.18 (aromatic epoxy resin, at 80° C.) | 216 311 310 487 | 4.129 | Generated |

TABLE 4

| | | | | |
|---|---|---|---|---|
| | Exothermic | Amount of | HOMO-LUMO | Generation |
| | peak time | heat generated | gap of cationic | of |
| Compound | (min) | (mJ/mg) | moiety (ev) | Lewis acid |

| | | | | |
|---|---|---|---|---|
| Comparative example 1 | 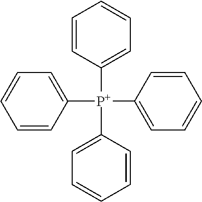 [SMILES: c1ccc([P+](c2ccccc2)(c2ccccc2)c2ccccc2)cc1] | No peak | 5.727 | Not Generated |
| | 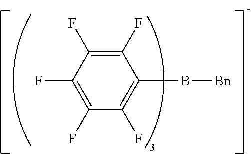 | | | |
| Comparative example 2 | 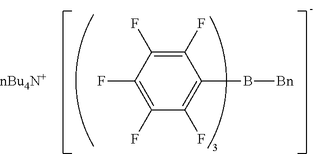 | No peak | 9.382 | Not Generated |
| Comparative example 3 | 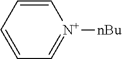 | No peak | 5.742 | Not Generated |
| | 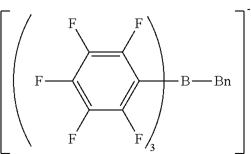 | | | |

As apparent from the results in the above tables, the compounds in Examples generated a Lewis acid in response to light. In addition, polymerization proceeded well using the compounds obtained in Examples.

### Evaluation of One-Component Stability

The compounds obtained in Examples and a typical photo acid generator, cumen-4-yl(p-tolyl)iodonium tetrakis(pentafluorophenyl)borate (hereinafter called iodonium borate salt) as a comparative compound were used to evaluate one-component stability.

One part by mass of the compound obtained in Example 8, the compound obtained in Example 9, or the iodonium borate salt was dissolved in 1 part by mass of propylene carbonate to prepare a solution.

One part by mass of the solution was mixed with 99 parts of an alicyclic epoxy resin (Celloxide 2021P, manufactured by Daicel), and the mixture was sealed and stored in a light shielded environment at 40° C.

The viscosity was measured to evaluate one-component stability. The initial viscosity (Day 0) was used as the baseline (thickening factor: 1), and the ratio of the viscosity after a determined period of days relative to the baseline was calculated as a thickening factor (viscosity at the time point of measurement/initial viscosity).

The following table shows the results.

TABLE 5

| | | Thickening |
|---|---|---|
| Compound | Day | factor |
| 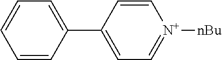 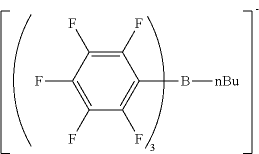 (Example 8) | 0 16 30 64 | 1.0 1.4 1.5 2.0 |
| 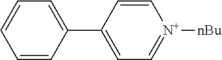 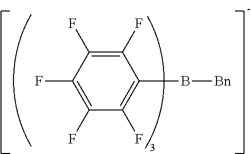 (Example 9) | 0 16 30 64 | 1.0 1.0 1.0 1.1 |
| 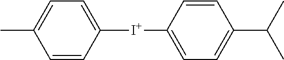 [SMILES: Cc1ccc([I+]c2ccc(C(C)C)cc2)cc1] 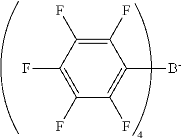 (Iodonium borate salt) | 0 16 30 64 | 1.0 1.7 5.3 43 |

As apparent from the results in the above table, the compounds obtained in Examples 8 and 9 showed higher one-component stability, and the increase in viscosity of the resin compositions was suppressed.

From these results, the compounds obtained in Examples were proven to be highly unlikely to generate Lewis acid in a light shielded environment and excellent in stability.

### Example 12

The same procedure as in Example 6 was performed except that quinolinium bromide was used instead of 1-benzylquinolinium bromide in Example 6, giving quinolinium benzyl-tris(pentafluorophenyl)borate as a viscous liquid.

H-NMR and F-NMR analysis confirmed that quinolinium benzyl-tris(pentafluorophenyl)borate (the following compound) was obtained.

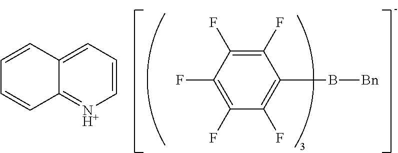

The obtained compound was used to examine the generation of a Lewis acid, and the generation of the Lewis acid was confirmed.

The HOMO-LUMO gap of the cationic moiety in the obtained compound was calculated as described above, and the calculated value was 4.287 eV.

### INDUSTRIAL APPLICABILITY

The compound of the present invention can generate a Lewis acid in response to light. Therefore, the compound of the present invention can be applied to various applications that can utilize a Lewis acid, for example, polymerization initiators and resists.

1. A compound comprising:
an anionic moiety having a central boron atom and an aryl group comprising at least one halogen atom; and
a cationic moiety,
the compound being capable of generating a Lewis acid from the anionic moiety in response to light irradiation.

2-13. (canceled)

14. The compound according to claim 1, wherein the anionic moiety is represented by Formula (1): 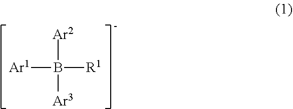
wherein Ar¹, Ar², and Ar³ are the same or different and each represent an aryl group optionally having a substituent; and R¹ represents a substituent.

15. The compound according to claim 14, wherein at least one of Ar¹, Ar², and Ar³ in Formula (1) is an aryl group having at least one halogen atom, and R¹ is an optionally substituted hydrocarbon group or a hydroxyl group.

16. The compound according to claim 1, wherein the cationic moiety comprises a cation having a HOMO-LUMO gap of 5.3 eV or less.

17. The compound according to claim 1, wherein the cationic moiety is unreactive with a Lewis acid.

18. The compound according to claim 1, wherein the cationic moiety generates no protonic acid in response to light.

19. The compound according to claim 1, wherein the cationic moiety is a cation having, as a central atom, a hetero atom selected from nitrogen, oxygen, or phosphorus.

20. The compound according to claim 1, wherein the light has a wavelength of 240 nm or more.

21. A photoinitiator comprising the compound according to claim 1.

22. A composition comprising the compound according to claim 1.

23. A method for producing a polymer from a polymerizable compound that polymerizes in the presence of a Lewis acid, the method comprising:
irradiating the composition of claim 22 with light in the presence of said polymerizable compound thereby producing said polymer.

24. The method according to claim 23, wherein the method is performed under heat.

25. A method for storing the composition of claim 22 in a light shielded environment comprising:
placing the composition of claim 22 in an environment shielded from light.
